(19) United States
(12) Patent Application Publication
(10) Pub. No.: US 2026/0182454 A1
(43) Pub. Date: Jun. 25, 2026

(54) SCALABLE CHIPLET ARRANGEMENT

(71) Applicant: Mercedes-Benz Group AG, Stuttgart (DE)

(72) Inventors: Francois Piednoel, Sunnyvale, CA (US); Charnjiv Bangar, Sunnyvale, CA (US)

(21) Appl. No.: 18/991,200

(22) Filed: Dec. 20, 2024

(51) Int. Cl. H01L 25/18; H01L 23/538

(52) U.S. Cl. CPC H10W 90/00; H10W 70/611; H10W 70/65

(57) ABSTRACT

A scalable chiplet-based system for integrated electronic control within a vehicle comprises several central chiplets, with each central chiplet being disposed along a substantially central axis of a substrate for housing the central chiplets. Several systems on chip perform vehicle operations of the vehicle, wherein each of the systems on chip communicate with one of the central chiplets through a respective die to die interconnect, and each die to die interconnect includes one or more main data paths and one or more side data paths. A chip to chip interconnect is between each of the central chiplets through which the central chiplets communicate.

### BACKGROUND

A system-on-chip (SoC) can comprise an integrated circuit that combines multiple components of a computer or electronic system onto a single chip, providing a compact and efficient solution for a wide range of applications. The main advantage of an SoC is its compactness and reduced complexity, since all the components are integrated onto a single chip. This reduces the need for additional circuit boards and other components, which can save space, reduce power consumption, and reduce overall cost. The components of an SoC are often referred to as chiplets, which are small, self-contained semiconductor components that can be combined with other chiplets to form the SoC.

Chiplets are designed to be highly modular and scalable, allowing for the creation of complex systems from smaller, simpler components and are typically designed to perform specific functions or tasks, such as memory, graphics processing, or input/output (I/O) functions. They may be interconnected with each other and with a main processor or controller using high-speed interfaces. Chiplets offer increased modularity, scalability, and manufacturing efficiency compared to traditional and current monolithic chip designs, as well as the ability to be tested individually before being combined into the larger system.

Universal Chiplet Interconnect Express (UCIe) provides an open specification for an interconnect and serial bus between chiplets, which enables the production of system-on-chip (SoC) packages with intermixed components from different silicon manufacturers. It is contemplated that autonomous vehicle computing systems may operate using chiplet arrangements that follow the UCIe specification.

### BRIEF DESCRIPTION OF THE DRAWINGS

FIG. 1 illustrates a system for integrated electronic control within a vehicle, in accordance with examples described herein.

FIG. 2A illustrates an example scalable chip arrangement for higher levels of autonomous vehicle operation, in accordance with examples described herein.

FIG. 2B illustrates an example scalable chip arrangement for lower levels of autonomous vehicle operation, in accordance with examples described herein.

FIG. 2C illustrates an example scalable chip arrangement with a pair of substrates connected through multiple chip-to-chip interconnects, in accordance with examples described herein.

FIG. 3A is a block diagram depicting an embodiment of an interconnect providing freedom from interference, in accordance with examples described herein.

FIG. 3B is a block diagram depicting an embodiment of an interconnect providing freedom from interference, according to examples described herein.

FIG. 3C is a block diagram depicting an embodiment of an interconnect providing freedom from interference, according to examples described herein.

FIG. 3D block diagram depicting an embodiment of an interconnect providing freedom from interference, according to examples described herein.

### DETAILED DESCRIPTION

Examples described herein pertain to the field of scalable, chiplet-based architectures within vehicle electronic systems, particularly focusing on integrating functionalities for autonomous driving, infotainment, and signal control within a unified electronic control unit (ECU). This technology is essential for creating scalable automotive systems that can support varying levels of autonomy (from level 2 to level 5) while reducing system costs and complexity. This architecture optimizes chip arrangement, redundancy, and interconnects through UCIe standards, which ensure the independence and compatibility of chiplets required for mixed-criticality systems.

ISO 26262 standards outline six levels of automation, ranging from Level 0 (no automation) to Level 5 (full automation). Level 0 involves no automation, where the driver of a vehicle is fully responsible. Level 1 includes driver assistance, such as adaptive cruise control, with the driver supervising all tasks. Level 2 adds partial automation, allowing the system to control steering and acceleration simultaneously under driver supervision. Level 3 introduces conditional automation, where the system can manage aspects of driving under specific conditions, but the driver must take over when requested. Level 4 is high automation, where the vehicle can handle driving tasks in certain environments without driver intervention. Finally, Level 5 is full automation, where the vehicle operates entirely independently in any environment without any human involvement.

Current automotive systems use multiple ECUs for each functionality within a vehicle (e.g., separate ECUs for autonomous driving, infotainment, and vehicle signal control). This segmented approach results in high production costs, increased complexity, and limited scalability for advancing levels of autonomy.

The architecture leverages a unique Universal Chiplet Interconnect Express (UCIe) configuration strategy to support scalable connection standards across all chiplets. Unlike existing designs, which require bespoke interconnects for each connection, this invention achieves scalability by reusing standard interconnects that ensure compatibility and continuity between different chiplets.

Modular chiplets can be added or reduced based on the desired autonomy level (e.g., level 2, level 3, level 4, or level 5). For level 2 autonomy, only one chiplet may be used, while for level 5 autonomy, multiple chiplets work together in parallel to increase processing capacity and redundancy.

The system scales by configuring multiple central chiplets, which interact horizontally in an array to increase computational capabilities as needed. For instance, Level 5 autonomy can be achieved by arranging three or four central chiplets, leveraging high inter-chiplet communication through UCIe.

By consolidating numerous microcontrollers and functions into chiplets, this system reduces the need for separate, weatherproof ECU housings, leading to significant cost savings. In addition, the system's use of a substrate-level chiplet arrangement as opposed to board-level integration allows for a more compact packaging that can incorporate more components.

The scalable structure of this architecture leverages multiple interconnect formats and chiplet configurations that range from basic (1×1) to advanced (4×1) setups. This adaptability ensures the system can be configured to different levels of autonomy without requiring entirely new hardware designs.

UCIe links provide the main communication channels within the chiplets, supporting high data transfer rates and redundancy. The UCIe architecture uses specific arrangements (4×1, 2×1, etc.) that offer scalability and fault tolerance. PCI-Express can be used as a supplementary interconnect standard alongside UCIe in certain configurations to support robust data communication across chiplets, ensuring system stability even if certain channels fail. In addition, GPIOs may be used for reset, functional safety, boot, and power management functions.

Through interconnected chiplets, the system enables redundancy across microcontrollers to enhance fault tolerance, such as allowing a neighboring chiplet to take over in the event of failure. The arrangement uses redundant UCIe lanes, allowing continued operation if one fails. For instance, a 4×1 arrangement has multiple UCIe lanes for backup, reducing the redundancy cost per chiplet as system size scales. The use of UCIe-based interconnects arranged in 4×1, 3×1, 2×1, and 1×1 configurations enables the system to balance performance and redundancy without incurring significant overhead. The design accommodates “degradation modes,” where failing components can still maintain partial functionality through alternate interconnect paths.

The architecture utilizes an array of modular chiplets connected in a scalable format on a single substrate. The architecture combines chiplets to perform tasks such as data processing, I/O handling, and machine learning acceleration within the SoC. These are configurable across multiple levels (e.g., level 2 to 5) to handle autonomous driving for a vehicle in a cost-efficient setup. The machine learning accelerator plays a critical role in computationally intensive tasks like perception and decision-making for autonomous operations.

In this scalable architecture, an individual chiplet can execute multiple vehicle control functions and share tasks with neighboring chiplets when needed. The configuration can expand from a single chiplet to arrays with numerous chiplets, enabling the system to support more advanced levels of autonomy by simply increasing the chiplet count.

For example, a high-end vehicle with level 5 autonomy would require an array of chiplets for processing the computational demands of autonomous driving, managing infotainment systems, and controlling signal communication with the vehicle. Redundant chiplets ensure that failures do not disrupt system operation. In contrast, a level 2 autonomous system could function with a single chiplet, reducing the overall cost and complexity while still providing reliable performance for basic driver assistance features.

Systems on chip can include one or more chiplets designed to perform specific vehicle functions to enable a vehicle to drive autonomously. The vehicle functions may also include features separate from autonomous driving. For example, the systems on chip may include the hardware necessary to operate a vehicle infotainment system or process other signals from the vehicle, such as indicator lights, parking sensors, a backup camera, etc. Automobiles are used as example vehicles, but the described system is applicable to other types of vehicles, including aircraft, ships, drones, etc.

In some aspects, a scalable chiplet-based system for integrated electronic control within a vehicle comprises a plurality of central chiplets, wherein each central chiplet of the plurality of central chiplets is disposed along a substantially central axis of a substrate for housing the plurality of central chiplets. A plurality of systems on chip performs one or more vehicle operations of the vehicle, wherein each of the systems on chip communicate with one of the plurality of central chiplets through a respective die to die interconnect, wherein each die to die interconnect includes one or more main data paths and one or more side data paths. A chip to chip interconnect is between each of the plurality of central chiplets through which the plurality of central chiplets communicate.

In some aspects, the plurality of central chiplets coordinate the one or more vehicle operations between a subset of the plurality of systems on chip connected to that central chiplet.

In some aspects, the plurality of systems on chip transmit production network data across the one or more main data paths.

In some aspects, the plurality of systems on chip transmit functional safety data across the one or more side data paths.

In some aspects, a ratio between the one or more main data paths and the one or more side data paths comprises a four-to-one ratio, a three-to-one ratio, a two-to-one ratio, or a one-to-one ratio.

In some aspects, the substrate accommodates an adjustable number of the plurality of central chiplets and the plurality of systems on chip based on a supported vehicle autonomy level.

In some aspects, the vehicle is configured to support a vehicle autonomy level of 4 or higher when the adjustable number of the plurality of central chiplets and/or the plurality of systems on chip exceeds a predetermined threshold.

In further aspects, the system includes a high-bandwidth memory positioned on top of each of the plurality of central chiplets.

In some aspects, at least one of the plurality of systems on chip operates a vehicle infotainment system.

In some aspects, at least one of the plurality of systems on chip processes signals from the vehicle.

In some aspects, the plurality of central chiplets communicate through the chip to chip interconnects to coordinate tasks performed by the plurality of systems on chip.

One or more aspects described herein provide that methods, techniques, and actions performed by a computing device are performed programmatically, or as a computer-implemented method. Programmatically, as used herein, means through the use of code or computer-executable instructions. These instructions can be stored in one or more memory resources of the computing device. A programmatically performed step may or may not be automatic.

One or more aspects described herein can be implemented using programmatic modules, engines, or components. A programmatic module, engine, or component can include a program, a sub-routine, a portion of a program, a software component, or a hardware component capable of performing one or more stated tasks or functions. As used herein, a module or component can exist on a hardware component independently of other modules or components. Alternatively, a module or component can be a shared element or process of other modules, programs, or machines.

Furthermore, one or more aspects described herein may be implemented through the use of instructions that are executable by one or more processors. These instructions may be stored on a computer-readable medium. Machines shown or described with figures below provide examples of processing resources and computer-readable media on which instructions for implementing some aspects can be stored and/or executed. In particular, the numerous machines shown or described include processors and various forms of memory for storing data and instructions. Examples of computer-readable media include permanent memory storage devices, such as hard disk drives on personal computers or servers. Other examples of computer storage media include portable storage units, such as CD or DVD units, flash or solid-state memory (such as carried on cell phones, tablets, and other consumer electronic devices), and magnetic memory. Computers, terminals, and network-enabled devices (e.g., mobile devices such as cell phones) are all examples of machines and devices that utilize processors, memory, and instructions stored on computer-readable media.

Alternatively, one or more examples described herein may be implemented through the use of dedicated hardware logic circuits that are comprised of an interconnection of logic gates. Such circuits are typically designed using a hardware description language (HDL), such as Verilog and VHDL. These languages contain instructions that ultimately define the layout of the circuit. However, once the circuit is fabricated, there are no instructions, and processing is performed by interconnected gates.

### System Overview

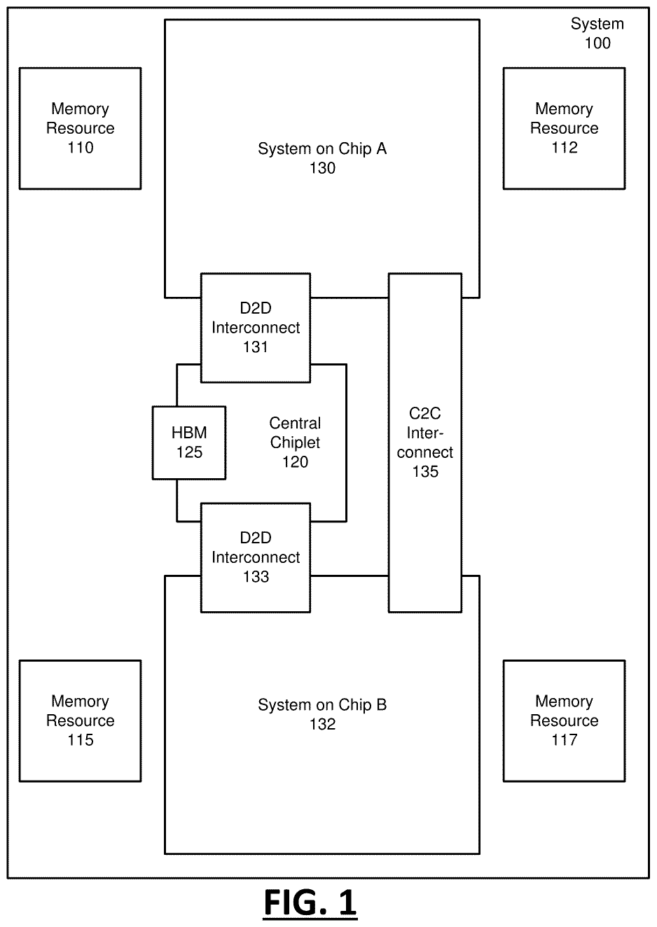

FIG. 1 illustrates a system 100 for integrated electronic control within a vehicle, in accordance with examples described herein. The system 100 includes a pair of systems on chip, System on Chip A 130 and System on Chip B 132, connected to a central chiplet 120 through die-to-die interconnects 131, 133, respectively. System on Chip A 130 and System on Chip B 132 are also connected through a chip-to-chip interconnect 135. The central chiplet 120 can include a high-bandwidth memory 125 to store data generated by the various chiplets of System on Chip A 130 and System on Chip B 132 in addition to other various memory resources 110, 112, 115, 117 included on the die. The HBM 125 may be positioned on top of the central chiplet 120 in some aspects or on the side in other aspects. In further aspects, memory including the memory resources 110, 112, 115, 117 can be placed on top of individual chiplets in the SoCs if the packaging technology allows it.

In various examples, System on Chip A 130 and System on Chip B 132 include chiplets that can store, alter, or otherwise process sensor data gathered by a sensor data input chiplet. In some aspects, System on Chip A 130 and System on Chip B 132 can include duplicate chiplets between them. In other aspects, the chiplets comprising System on Chip A 130 and System on Chip B 132 are unique to each SoC. The SoCs can include an autonomous drive chiplet that can perform the perception, sensor fusion, trajectory prediction, and/or other autonomous driving algorithms of the autonomous vehicle. The autonomous drive chiplet can be connected to a dedicated HBM-RAM chiplet in which the autonomous drive chiplet can publish all status information, variables, statistical information, and/or processed sensor data as processed by the autonomous drive chiplet.

In various examples, the SoCs can further include a machine-learning (ML) accelerator chiplet that is specialized for accelerating machine-learned or AI workloads, such as image inferences or other sensor inferences using machine learning, in order to achieve high performance and low power consumption for these workloads. The ML accelerator chiplet can include an engine designed to efficiently process graph-based data structures, which are commonly used in AI workloads, and a highly parallel processor, allowing for efficient processing of large volumes of data. The ML accelerator chiplet can also include specialized hardware accelerators for common AI operations such as matrix multiplication and convolution as well as a memory hierarchy designed to optimize memory access for AI workloads, which often have complex memory access patterns.

The SoCs can further include general compute chiplets that provide general purpose computing for the system. For example, the general compute chiplets can comprise high-powered central processing units and/or graphical processing units that can support the computing tasks of the central chiplet, autonomous drive chiplet, and/or the ML accelerator chiplet.

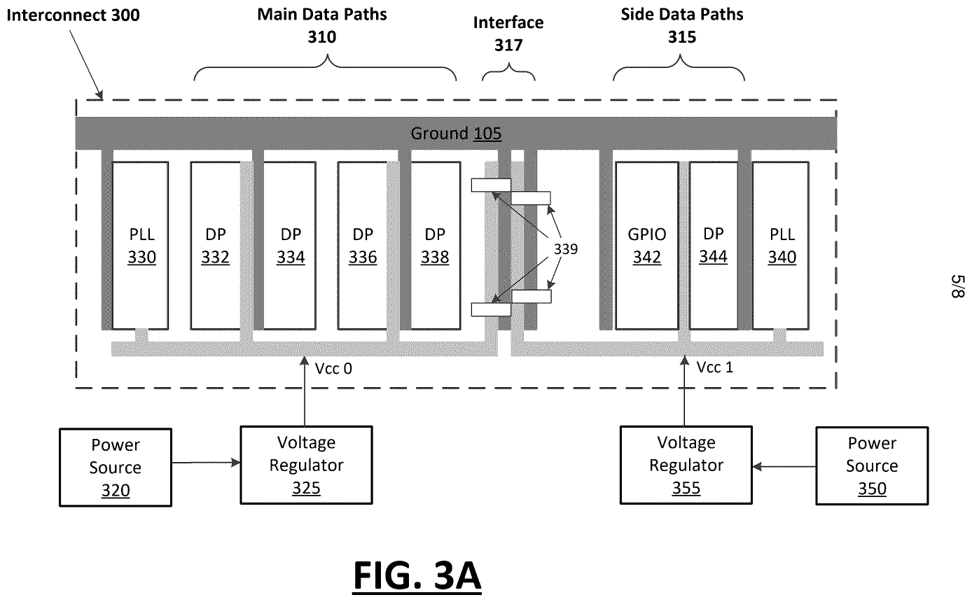

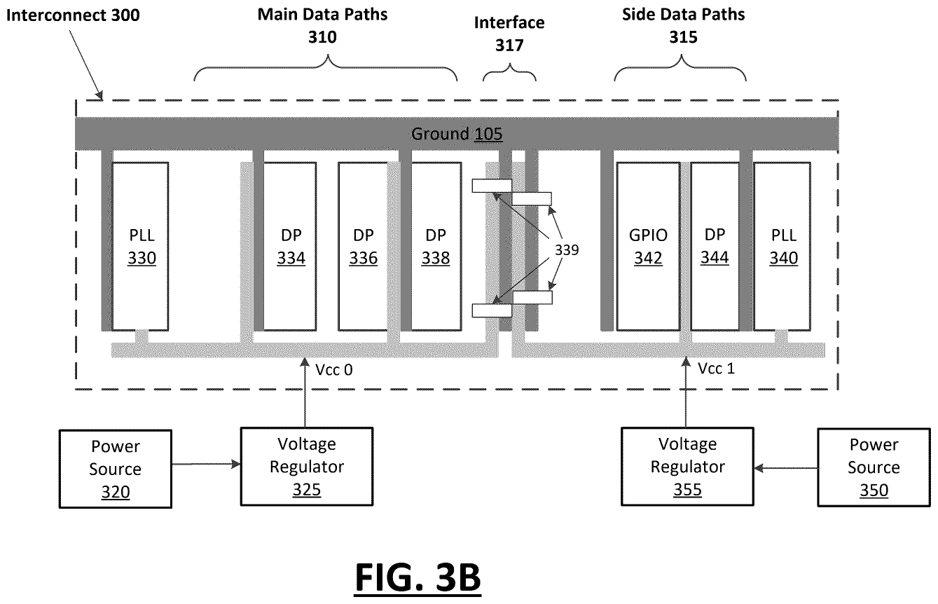

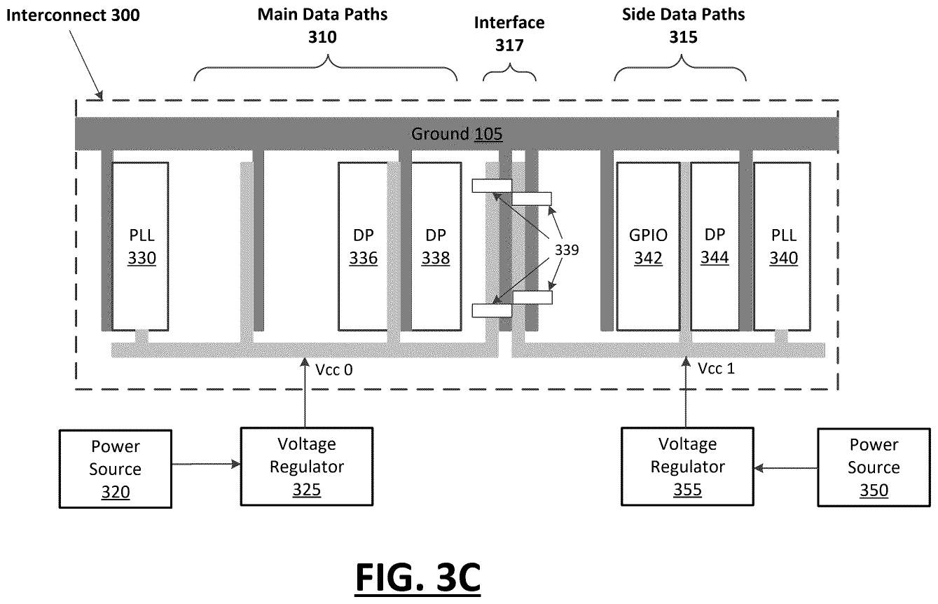

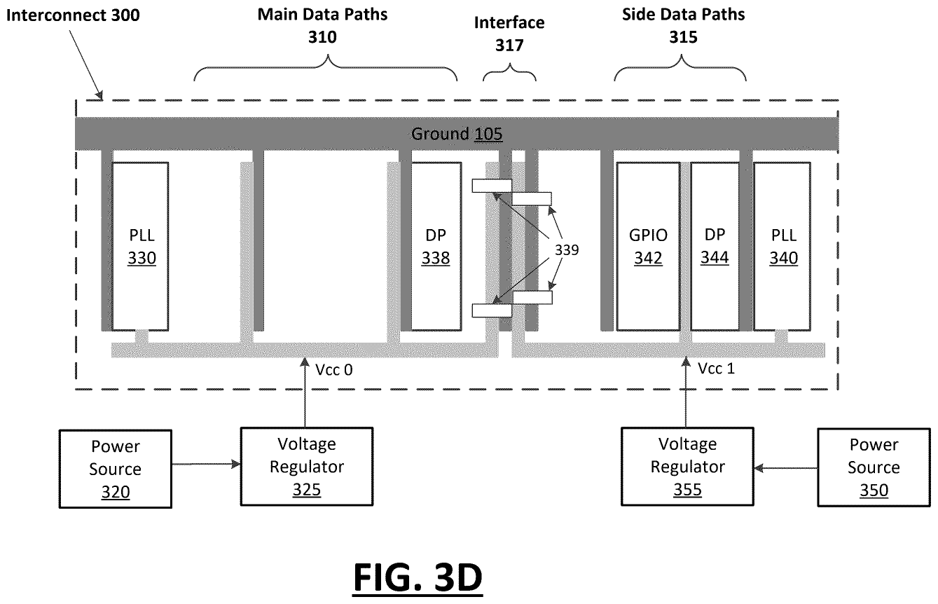

As provided herein, the D2D interconnects 131, 133 can include high-bandwidth data paths used for general data purposes to the cache memory and high-reliability data paths to transmit functional safety (FuSa) and scheduler information to the central chiplet 120. Depending on bandwidth requirements, the D2D interconnects 131, 133 may include more than one data path. For example, the D2D interconnects 131, 133 can include four data paths to support higher bandwidth communications between the SoCs and the central chiplet 120. In some aspects, each of the D2D interconnects 131, 133 have the same hardware for ease of production. For example, each D2D interconnect 131, 133 may include the same number of data paths connecting to the central chiplet 120. In other aspects, the D2D interconnects 131, 133 have different internal hardware configurations to meet the needs of the vehicle in operating at a given level of autonomy. As described with respect to FIG. 3, the D2D interconnects 131, 133 are scalable to accommodate an adjustable number, either more or fewer, of data paths depending on the needs of the vehicle in operating at a given level of autonomy. For example, a vehicle may require four high bandwidth data paths to meet a predetermined threshold amount of redundancy, computing power, storage, etc. to safely operate in a level 4 or level 5 autonomous mode. Similarly, the D2D interconnects 131, 133 and C2C interconnect 135 may include multiple high-reliability data paths using separate interfaces, such as one PCIe interface and one general purpose input/output (GPIO) interface. Having multiple high-reliability data paths provides additional redundant backup mechanisms to enable the vehicle to safely operate at higher levels of autonomy. In some examples, the C2C interconnect 135 between System on Chip A 130 and System on Chip B 132 is used to maintain the state of the machine between the two SoCs.

In one aspect, the D2D interconnects 131, 133 implement the Universal Chiplet Interconnect Express (UCIe) standard and communicate through an indirect mode to allow each of the chiplet host processors to access remote memory as if it were local memory. This is achieved by using a specialized Network-on-Chip (NoC) Network Interface Unit (NIU) (e.g., which allows freedom of interferences between devices connected to the network) that provides hardware-level support for remote direct memory access (RDMA) operations. In UCIe indirect mode, the host processor sends requests to the NIU, which then accesses the remote memory and returns the data to the host processor. This approach allows for efficient and low-latency access to remote memory, which can be particularly useful in distributed computing and data-intensive applications. Additionally, UCIe indirect mode provides a high degree of flexibility, as it can be used with a wide range of different network topologies and protocols.

In various implementations, a shared memory on the central chiplet 120 can store programs and instructions for performing autonomous driving tasks. The shared memory of the central chiplet 120 can further include a reservation table that provides the various chiplets with the information needed (e.g., sensor data items and their locations in memory) for performing their individual tasks. In various aspects, the central chiplet 120 also includes a large cache memory, which supports invalidate and flush operations for stored data.

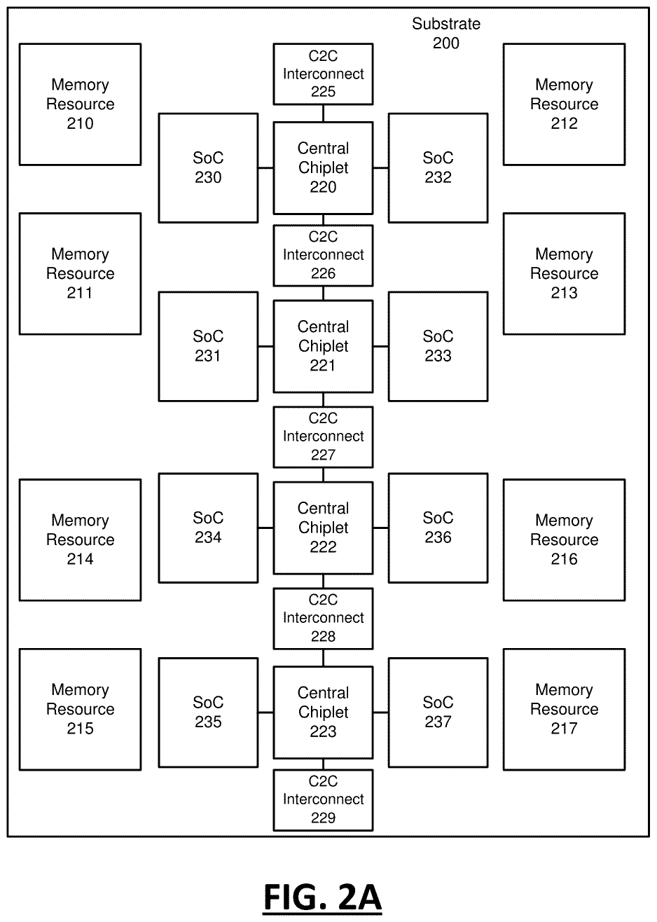

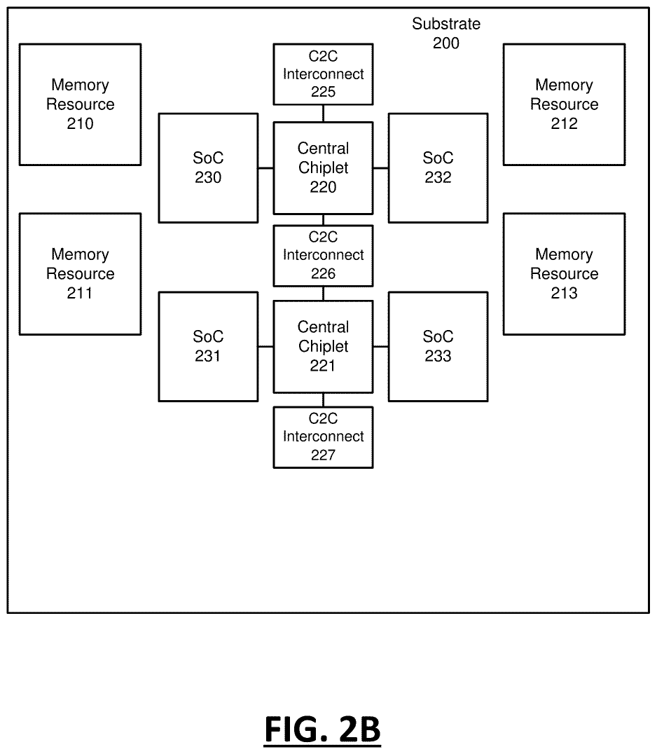

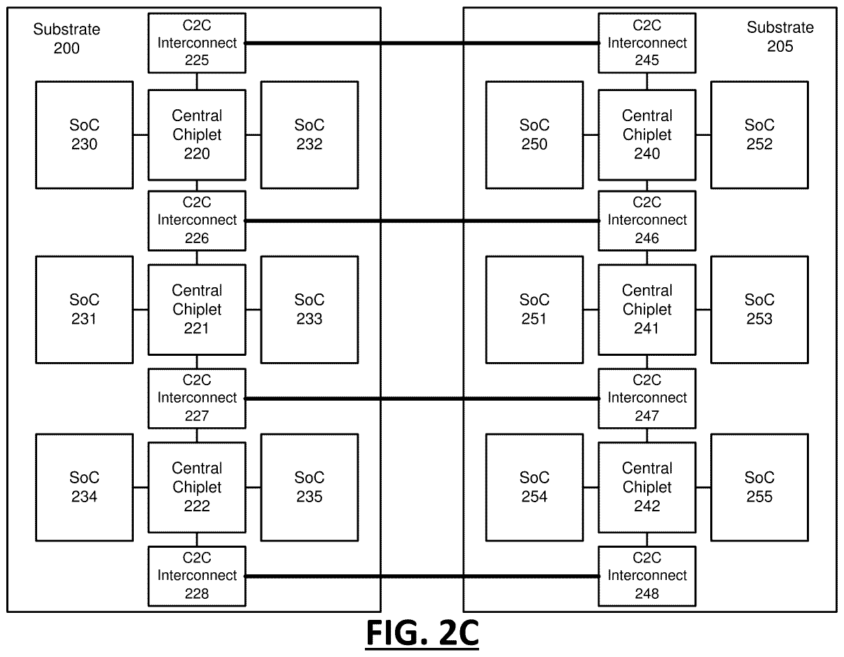

FIG. 2A illustrates an example scalable chip arrangement for higher levels of autonomous vehicle operation, in accordance with examples described herein. The scalable chip arrangement is disposed on a substrate 200 with central chiplets 220-223 disposed along a substantially central axis of the substrate 200. The substrate 200 also includes chip-to-chip interconnects 225-229 that connect each of the central chiplets 220-223. As shown, each of the central chiplets 220-223 is connected to a pair of systems on chip 230-237 in an arrangement that mirrors that illustrated in FIG. 1. However, any central chiplet 220-223 may be connected to only a single SoC. Furthermore, the substrate is scalable to accommodate an adjustable number, either more or fewer, central chiplets 220-223 depending on the needs of the vehicle in operating at a given level of autonomy. For example, a vehicle may require four central chiplets 220-223 to meet a predetermined threshold amount of redundancy, computing power, storage, etc. to safely operate in a level 4 or level 5 autonomous mode.

In some aspects, each of the C2C interconnects 225-229 have the same hardware for ease of production. For example, each C2C interconnect 225-229 may include the same number of data paths connecting the central chiplets 220-223. In other aspects, the C2C interconnects 225-229 have different internal hardware configurations to meet the needs of the vehicle in operating at a given level of autonomy.

Each of the SoCs 230-237 can include chiplets for operating an autonomous vehicle as described with respect to FIG. 1. The SoCs 230-237 can also include chiplets that perform vehicle operations that would normally be housed in separate electronic control units (ECUs). For example, SoC 230 may be a chiplet that operates a vehicle infotainment system, and SoC 231 may be a chiplet that controls signals from the vehicle. Other operations that the SoCs perform may include stability control, traction control, and an anti-lock braking system.

FIG. 2B illustrates an example scalable chip arrangement for lower levels of autonomous vehicle operation, in accordance with examples described herein. In this example with only two central chiplets 320, 321, the vehicle may not meet the threshold requirement for higher levels of autonomous operation. Accordingly, a vehicle with the package illustrated in FIG. 2B may only be capable of level 2 autonomy, as opposed to the level 4 or level 5 autonomy achievable with the package illustrated in FIG. 2A.

In some aspects, hardware failures may result in a degradation of performance of an autonomous vehicle, reducing the level of autonomy possible. For example, a vehicle may be equipped with a package such as the one illustrated in FIG. 2A and therefore be capable of operating at level 5. However, on detecting a failure within one or more of the components, the amount of remaining hardware may fall behind the predetermined threshold requirement of redundancy, computing power, memory, etc. to remain operating at level 5 autonomy. In such a case, the vehicle may lower the maximum level of safe autonomous operation based on the remaining hardware configuration upon detecting such a fault.

FIG. 2C illustrates an example scalable chip arrangement with a pair of substrates connected through multiple chip-to-chip interconnects. As shown, the left substrate 200 contains chiplets for a first chip, and the right substrate 205 contains chiplets for a second chip. The first and second chips are connected through their respective chip-to-chip interconnects 225-228, 245-248.

In some aspects, the chip-to-chip interconnects connect central chiplets on the same substrate together using a first type of interface and connect to another chip-to-chip interconnect on a different substrate using a second type of interface. For example, the C2C interconnect 226 on the first substrate 200 connects the central chiplet 220 and the central chiplet 221 with data paths using the UCIe interface. The C2C interconnect 226 also connects to the C2C interconnect 246 on the second substrate 205 using the Peripheral Component Interconnect Express (PCIe) interface.

In some aspects, the first substrate 200 and the second substrate 205 comprise a system with the chips of the first substrate 200 acting as primary and the chips of the second substrate 205 acting as a secondary backup. With multiple connections between the two substrates acting as redundant backup mechanisms, the system can ensure a high level of reliability even in the event of hardware failure. The system can route data using the shortest path across the various interconnects in normal conditions but may use any available route if one or more of the chip-to-chip interconnects fail.

### Example Interconnects

FIGS. 3A through 3D are block diagrams depicting example interconnects, in accordance with examples described herein. Referring to FIG. 3A, the interconnect can include a set of main data paths 310 comprising data paths 332, 334, 336, and 338, and a set of side data paths 315 comprising a general purpose input/output data path 342 and data path 344. As provided herein, the interconnect 300 may comprise any combination and ratio of data paths in the main versus the side. As further provided herein, it is contemplated that any component shown in FIGS. 3A, 3B, 3C, and 3D may be included or omitted in an embodiment. For example, any of the embodiments in FIGS. 3A, 3B, 3C, and 3D may include or omit the general purpose input/output data path 342. In an embodiment, the main data path(s) 310 may refer to the main data path (also referred to as main bus) in the UCIe specification, and the side data path(s) may refer to the side data path (also referred to as side bus) in the UCIe specification. As an example, certain embodiments may provide for the main data path having 36 Gbps capacity for transmitting and receiving data, whereas the side data path may have 800 Mbps capacity. It is contemplated that future embodiments may have increased capacity for data transmissions in both the main and side data paths.

Referring to the embodiment shown in FIG. 3B, the interconnect 300 includes three data paths 334, 336, and 338, whereas the side includes one data path 344. As another example, referring to FIG. 3C, the interconnect 300 includes a two-to-one ratio of data paths between the main data paths 336 and 338 and the side data path 344. As yet another example, referring to FIG. 3D, the main data path includes a single data path 338 whereas the side data path also includes a single data path 344. With reference to each of FIGS. 3A, 3B, 3C, and 3D, the phase-locked loop 330 of the main data paths 310 remains fixed despite the changes in configurations of the main data paths 310. This allows for compatibility between each of the interconnects 300 in FIGS. 3A, 3B, 3C, and 3D, such that any embodiment shown can connect with any other embodiment.

Furthermore, each of the interconnects 300 shown in FIGS. 3A, 3B, 3C, and 3D can include common components, and as such, the description of these components may be shared between the different embodiments. For example, the description of the shared ground 305 when referring to FIG. 3A may also describe the shared ground 305 as shown in FIGS. 3B, 3C, and 3D. Still further, description of the components external to the interconnect 300, such as the first power source 320, first voltage regulator 325, second power source 350, and second voltage regulator 355, may also be shared between the different embodiments as shown and described with respect to FIGS. 3A, 3B, 3C, and 3D.

As provided herein, the term “data path” may be used interchangeably with “lane,” “slice,” or any other suitable term for a component of the interconnect 300 through which data is communicated. In certain implementations, the set of main data paths 310 and/or the set of side data paths 315 may include a general-purpose input/output data path 342 that may be used for any purpose, such as functional safety health monitoring or clock rate configuration.

In various examples, the main data paths 310 are electrically isolated from the side data paths 315 based on a shared ground 305, a first power source 320 that provides power to a first voltage regulator 325, and a second power source 350 that provides power to a second voltage regulator 355. The first voltage regulator 325 provides constant voltage to a first phase-locked loop 330 associated with the main data paths 310, and the second voltage regulator 355 provides constant voltage to a second phase-locked loop associated with the side data paths 315. As provided herein, the first power source 320 can comprise a first battery or power supply that draws power from a source that is independent from power source 350. Accordingly, if power source 350 fails, power source 320 may still provide power to the main data paths 310. Likewise, the second power source 350 can comprise a second battery or second power supply that draws power from a source that is independent from power source 320. Accordingly, if power source 320 fails, power source 350 may still provide power to the side data paths 315.

Each voltage regulator 325, 355 receives electrical current from their respect power sources 320, 350, which can comprise direct current (e.g., from one or more batteries) or alternating current from an alternator, wall socket, etc. The voltage regulators 325, 355 can function to maintain a constant voltage (Vcc 0 and Vcc 1) for each of the main data paths 310 and the side data paths 315. The phase-locked loop 330 of the main data paths 310 and the phase-locked loop 340 of the side data paths 315 can each comprise a control system that generates output signals that have fixed phase relative to phases of the voltage signals from the voltage regulators 325, 355.

According to various examples, an interface 317 can electrically isolate the main data paths 310 from the side data paths 315 to provide freedom from interference between the two. As such, if a failure occurs in one or more components associated with the main data paths 310, the side data paths 315 may continue to operate. Likewise, if a failure occurs in one or more components associated with the side data paths 315, the main data paths 310 may continue to operate.

As shown in FIG. 3A, the shared ground 305 comprises a set of spires or cavitations that are disposed between the phase-locked loop 330 and certain data paths 332, 334, 336, 338 of the main data paths 310, and the phase-locked loop 340 and certain data paths 342, 344 of the side data paths 315. In accordance with examples provided herein, the arrangement of the shared ground 305 spires or cavitations are shown in FIG. 3A for illustrative purposes, and may be arranged in any suitable manner so as provide freedom from interference between the main data paths 310 and the side data paths 315. For example, the shared ground 305 can include spires or cavitations between phase-locked loop 330 and data path 332, between data path 334 and data path 336, and/or between data path 342 and 344.

In further implementations, the interface 317 between the main data paths 310 and the side data paths 315 can include multiple spires or cavitations for the shared ground 305, and can further comprise an interface 317 between one or more spires of the electrical conductor for the main data paths 310 (providing voltage Vcc 0) and one or more spires of the electrical conductor for the side data paths 315 (providing voltage Vcc 1). One or more de-capping components 339 (e.g., decoupling capacitors) can further be included in the interface 317 to eliminate any transient noise from Vcc 0 or Vcc 1.

In various examples, the main data paths 310 can transmit production data (e.g., sensor data) over a high-performance network of the system-on-chip (SoC). The side data paths 315 can transmit functional safety (FuSa) data over a high-reliability network to perform health monitoring tasks for the hardware components of the SoC. In further examples, the side data paths 315 can transmit clock signals between the chiplets of the SoC. For example, the side data paths 315 can include a first lane for transmitting clock signals and a second lane for transmitting FuSa information (e.g., hardware performance data, temperature information, data requests and acknowledgments, and the like).

For autonomous vehicle implementations, the main data paths 310 can functions to transmit raw or processed sensor data between chiplets and caches of the SoC. In particular, the sensor data can be obtained from a sensor system of the vehicle, which can include any combination of cameras, LIDAR sensors, radar sensors, ultrasonic sensors, proximity sensors, and the like. The individual chiplets of the SoC can each process the sensor data from the various sensors to provide a sensor view of the surrounding environment of the vehicle (e.g., a dynamic, three-dimensional sensor-fused view), and certain chiplets can perform inference operations on the sensor view.

Examples described herein are related to the use of a computer system for implementing the techniques described. According to one aspect, those techniques are performed by a computer system in response to a processor executing one or more sequences of one or more instructions contained in main memory. Such instructions may be read into main memory from another machine-readable medium, such as a storage device. Execution of the sequences of instructions contained in main memory causes the processor to perform the process steps described herein. In alternative aspects, hard-wired circuitry may be used in place of or in combination with software instructions to implement aspects described herein. Thus, aspects described are not limited to any specific combination of hardware circuitry and software.

Although examples are described in detail herein with reference to the accompanying drawings, it is to be understood that the concepts are not limited to those precise examples. Accordingly, it is intended that the scope of the concepts be defined by the following claims and their equivalents. Furthermore, it is contemplated that a particular feature described either individually or as part of an example can be combined with other individually described features, or parts of other examples, even if the other features and examples make no mentioned of the particular feature. Thus, the absence of describing combinations should not preclude having rights to such combinations.

What is claimed is:

1. A scalable chiplet-based system for integrated electronic control within a vehicle, comprising:
a plurality of central chiplets, wherein each central chiplet of the plurality of central chiplets is disposed along a substantially central axis of a substrate for housing the plurality of central chiplets;
a plurality of systems on chip to perform one or more vehicle operations of the vehicle, wherein each of the systems on chip communicate with one of the plurality of central chiplets through a respective die to die interconnect, wherein each die to die interconnect includes one or more main data paths and one or more side data paths; and
a chip to chip interconnect between each of the plurality of central chiplets through which the plurality of central chiplets communicate.

2. The system of claim 1, wherein the plurality of central chiplets coordinate the one or more vehicle operations between a subset of the plurality of systems on chip connected to that central chiplet.

3. The system of claim 1, wherein the plurality of systems on chip transmit production network data across the one or more main data paths.

4. The system of claim 1, wherein the plurality of systems on chip transmit functional safety data across the one or more side data paths.

5. The system of claim 1, wherein a ratio between the one or more main data paths and the one or more side data paths comprises a four-to-one ratio, a three-to-one ratio, a two-to-one ratio, or a one-to-one ratio.

6. The system of claim 5, wherein the substrate accommodates an adjustable number of the plurality of central chiplets and the plurality of systems on chip based on a supported vehicle autonomy level.

7. The system of claim 6, wherein the vehicle is configured to support a vehicle autonomy level of 4 or higher when the adjustable number of the plurality of central chiplets and/or the plurality of systems on chip exceeds a predetermined threshold.

8. The system of claim 1, further comprising a high-bandwidth memory positioned on top of each of the plurality of central chiplets.

9. The system of claim 1, wherein at least one of the plurality of systems on chip operates a vehicle infotainment system.

10. The system of claim 1, wherein at least one of the plurality of systems on chip processes signals from the vehicle.

11. The system of claim 1, wherein the plurality of central chiplets communicate through the chip to chip interconnects to coordinate tasks performed by the plurality of systems on chip.

12. A system on chip package for integrated electronic control within a vehicle, comprising:
a plurality of central chiplets, wherein each central chiplet of the plurality of central chiplets is disposed along a substantially central axis of a substrate for housing the plurality of central chiplets;
a plurality of systems on chip to perform one or more vehicle operations of the vehicle, wherein each of the systems on chip communicate with one of the plurality of central chiplets through a respective die to die interconnect, wherein each die to die interconnect includes one or more main data paths and one or more side data paths; and
a chip to chip interconnect between each of the plurality of central chiplets through which the plurality of central chiplets communicate.

13. The system on chip package of claim 1, wherein the plurality of central chiplets coordinate the one or more vehicle operations between a subset of the plurality of systems on chip connected to that central chiplet.

14. The system on chip package of claim 1, wherein the plurality of systems on chip transmit production network data across the one or more main data paths.

15. The system on chip package of claim 1, wherein the plurality of systems on chip transmit functional safety data across the one or more side data paths.

16. The system on chip package of claim 1, wherein a ratio between the one or more main data paths and the one or more side data paths comprises a four-to-one ratio, a three-to-one ratio, a two-to-one ratio, or a one-to-one ratio.

17. The system on chip package of claim 5, wherein the substrate accommodates an adjustable number of the plurality of central chiplets and the plurality of systems on chip based on a supported vehicle autonomy level.

18. The system on chip package of claim 6, wherein the vehicle is configured to support a vehicle autonomy level of 4 or higher when the adjustable number of the plurality of central chiplets and/or the plurality of systems on chip exceeds a predetermined threshold.

19. The system on chip package of claim 1, further comprising a high-bandwidth memory positioned on top of each of the plurality of central chiplets.

20. A multiple system on chip (mSoC) for integrated electronic control within a vehicle, comprising:
a plurality of central chiplets, wherein each central chiplet of the plurality of central chiplets is disposed along a substantially central axis of a substrate for housing the plurality of central chiplets;
a plurality of systems on chip to perform one or more vehicle operations of the vehicle, wherein each of the systems on chip communicate with one of the plurality of central chiplets through a respective die to die interconnect, wherein each die to die interconnect includes one or more main data paths and one or more side data paths; and
a chip to chip interconnect between each of the plurality of central chiplets through which the plurality of central chiplets communicate.
